(19) United States
(12) Patent Application Publication
(10) Pub. No.: US 2014/0224516 A1
(43) Pub. Date: Aug. 14, 2014

(54) IMPACT RESISTANT HOUSING FOR DATA SIGNAL DEVICES

(71) Applicant: JJS COMMUNICATIONS CO., LTD., Taipei City (TW)

(72) Inventor: SHOU-YING WANG, Taipei City (TW)

(73) Assignee: JJS COMMUNICATIONS CO., LTD., Taipei City (TW)

(21) Appl. No.: 13/763,193

(22) Filed: Feb. 8, 2013

(51) Int. Cl. H05K 5/02

(52) U.S. Cl. CPC H05K 5/0217
USPC 174/50

(57) ABSTRACT

An impact resistant housing used to house devices to split, amplify, or modulate signals for CATV, satellite and phone systems comprises a base and a cover. The base includes a bottom, a top opening, and a peripheral recession portion that is recessed from internal walls of the base and located adjacent to the top opening. The cover includes an internal surface. The internal surface has peripheries soldered to the peripheral recession portion of the base and a protruded portion that is provided peripherally and located adjacent to the peripheries of the cover. When the cover is soldered to the base, the protruded portion of the cover borders with the internal walls of the base. By such structural design, the circuit board and electrical signal lines placed in the housing can be protected when the case is impacted by external force.

### BACKGROUND OF THE INVENTION

1. Field of the Invention

The present invention relates to a housing for signal transmission devices and, more particularly, to an impact resistant housing for data signal devices, especially for devices commonly known as splitters used in the cable television, phone and satellite industries to split the transmission signals. Thereby, the present invention provides an enhanced structural housing so as to protect the circuit board and signal lines placed inside the housing from any impact of external force to the housing.

2. Description of the Prior Art

With the increased popularity of cable television, satellite and phone systems for delivery of video and data services, various devices are used to split, amplify, and limit signal transmission within the customers' home. Such devices usually have an input terminal for receiving electrical signals from the cable/satellite signal and plural output terminals for distributing these signals to various locations.

Conventionally, a housing for such devices is provided to protect the circuit board and various electronic parts located therein. A conventional housing usually contains an opening and a cover. The cover is soldered or otherwise affixed onto the opening of the body of the housing.

A common problem with current housings is that conventional housings lack structural strength to withstand an impact from a foreign object.

In fact, the structure of conventional housings is not strong enough to resist the impact from external force because the connection between the cover and the housing is relatively weak. Therefore, when external force is exerted on the cover of the signal housing, the cover would collapse so as to impair the circuit board and the electrical signals passing through the device.

Since the structural strength of the conventional housing for these devices is not sufficient to resist the impact from external force, there is a need to design a housing with sufficient structural strength to withstand a blow from an external impact force to protect the circuit board and electric signal mechanisms therein.

### SUMMARY OF THE INVENTION

The main object of the present invention is to provide an impact resistant housing for splitters, amplifiers, couplers, and simpler devices used for data and video transmission with enhanced structural strength, so as to protect the circuit board and electrical signal mechanisms therein from the impact of external force.

In order to achieve above object, the present invention provides an impact resistant housing comprising a base and a cover. The base includes a bottom, a top opening, and a peripheral recession portion that is recessed from internal walls of the base and located adjacent to the top opening. The cover includes an internal surface, where the internal surface has peripheries that may be soldered or otherwise attached to the peripheral recession portion of the base and is provided peripherally with a protruded portion adjacent to the peripheries of the cover. When the cover is attached to the base, the protruded portion of the cover borders with the internal walls of the base.

In implementation, the cover further includes at least one strengthening rib disposed on the internal surface of the cover. Preferably, the cover includes plural strengthening ribs and the plural strengthening ribs are arranged to cross with each other or are arranged to be in Y shape, for further structural stability.

In implementation, the base further includes at least one support seat for supporting the strengthening ribs and each support seat is protruded from one internal wall of the base. Preferably, each support seat includes a vertical part and a recessed part provided on top of the vertical part.

In implementation, the base further includes at least one anti-impact bar, each of which is made by rigid material and is provided inside the base. Preferably, each anti-impact bar is provided on the bottom of the base; and/or each anti-impact bar has a surface facing the internal surface of the cover; and/or each anti-impact bar is made by metal or other kinds of material with similar strength; and/or each anti-impact bar is configured to be a T-shape bar.

The following detailed description, given by way of example, and is not intended to limit the invention solely to the embodiments described herein, will best be understood in conjunction with the accompanying drawings.

### BRIEF DESCRIPTION OF THE DRAWINGS

FIG. 1 is a perspective view showing a first embodiment of an impact resistant housing for devices used to split, amplify, or modulate electronic signals according to the present invention.

FIG. 2 is a perspective view showing the base in the first embodiment of the impact resistant housing according to the present invention.

FIG. 3 is a perspective view showing a first type of the cover in the first embodiment of the impact resistant housing according to the present invention.

FIG. 4 is a perspective view showing a second type of the cover in the first embodiment of the impact resistant housing according to the present invention.

FIG. 5 is a perspective view showing a base in a second embodiment of the impact resistant housing according to the present invention.

FIG. 6 is a perspective view showing a cover in the second embodiment of the impact resistant housing according to the present invention.

### DETAILED DESCRIPTION OF THE PREFERRED EMBODIMENTS

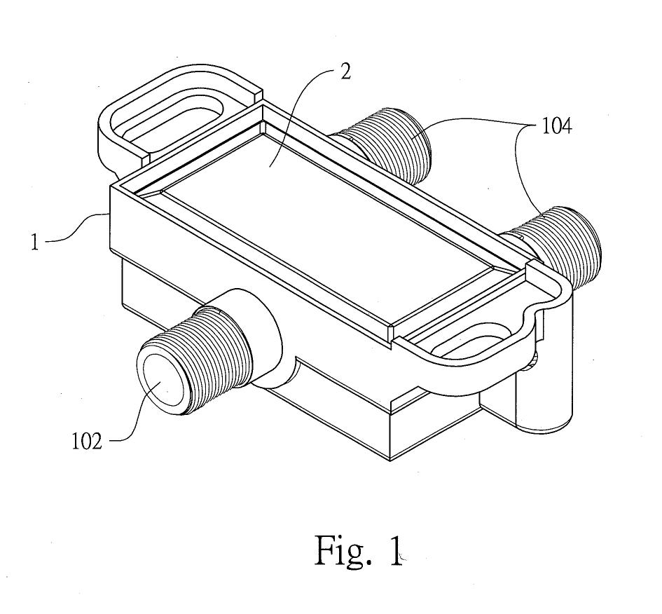

The present invention discloses an impact resistant housing used for devices involved in the transmission of CATV, satellite and phone signals. FIGS. 1˜4 illustrate a first embodiment of the impact resistant housing according to the present invention. As shown in FIG. 1, the impact resistant housing comprises a base 1 and a cover 2, where the base 1 is provided on its outer peripheries with one signal input terminal 102 and two signal output terminals 104.

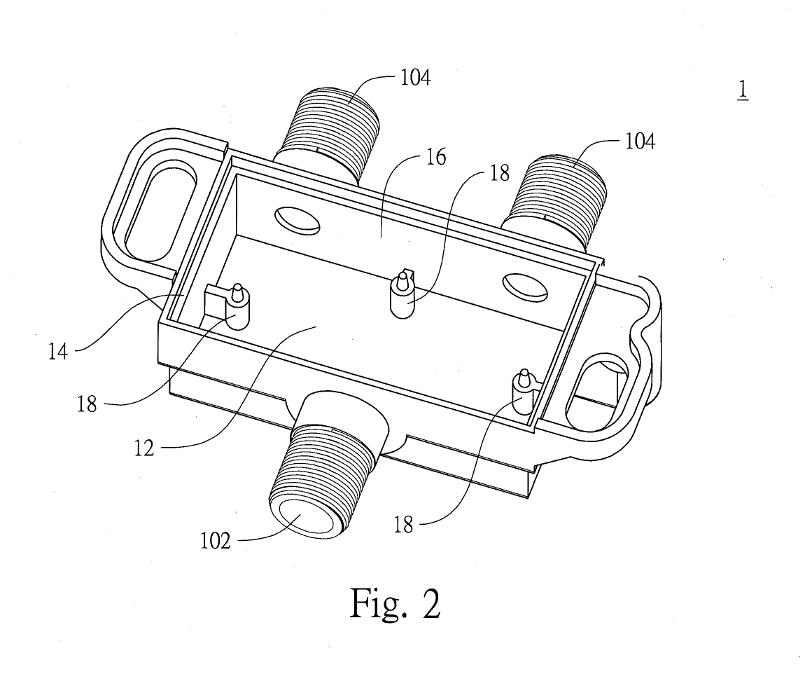

Please refer to FIG. 2, which shows the perspective view of the base 1. As shown in FIG. 2, the base 1 includes a bottom 12, a top opening, and a peripheral recession portion 14. The peripheral recession portion 14 is recessed from the internal walls 16 of the base 1 and is located adjacent to the top opening. Also, in the first embodiment, the base 1 includes a connection point 18 for positioning a circuit board (not shown in FIG. 2) inside the base 1.

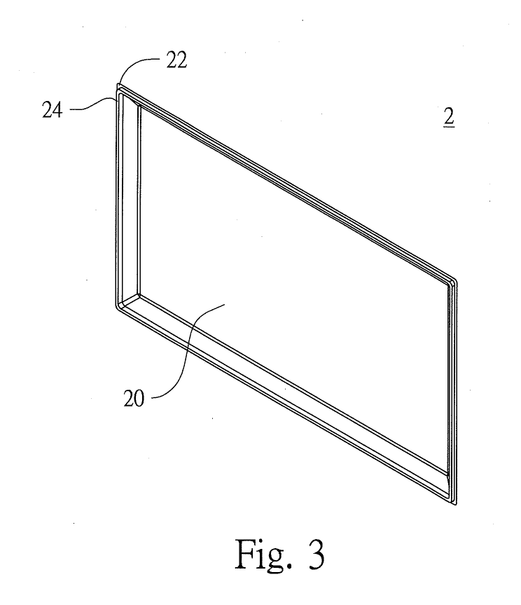

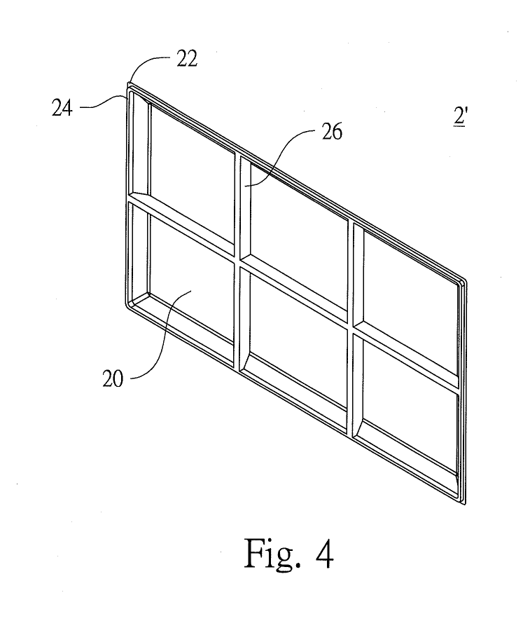

FIGS. 3 and 4 respectively illustrate two types of a cover in the first embodiment according to the present invention. Regarding the first type, as shown in FIG. 3, the cover 2 includes an internal surface 20 and the internal surface 20 has peripheries 22 and a protruded portion 24. The protruded portion 24 is disposed peripherally on the internal surface 20 and located adjacent to the peripheries 22 of the cover 2.

The peripheries 22 of the cover 2 are attached to the peripheral recession portion 14 of the base 1 by suitable means such as soldering with tin or nickel. When the cover 2 is attached to the base 1, the protruded portion 24 of the cover 2 borders with the internal walls 16 of the base 1. Thereby, it could strengthen the connection between the cover 2 and the base 1, so as to provide better resistance against the impact from an external force.

FIG. 4 shows the second type of the cover 2′. As shown in FIG. 4, in addition to the peripheries 22 and the protruded portion 24, a plurality of strengthening ribs 26 are provided on the internal surface 20 of the cover 2. In this embodiment, these strengthening ribs 26 are arranged to cross with each other. By this arrangement, the strength of the cover 2′ could be further enhanced, so as to provide better resistance against the impact from external force.

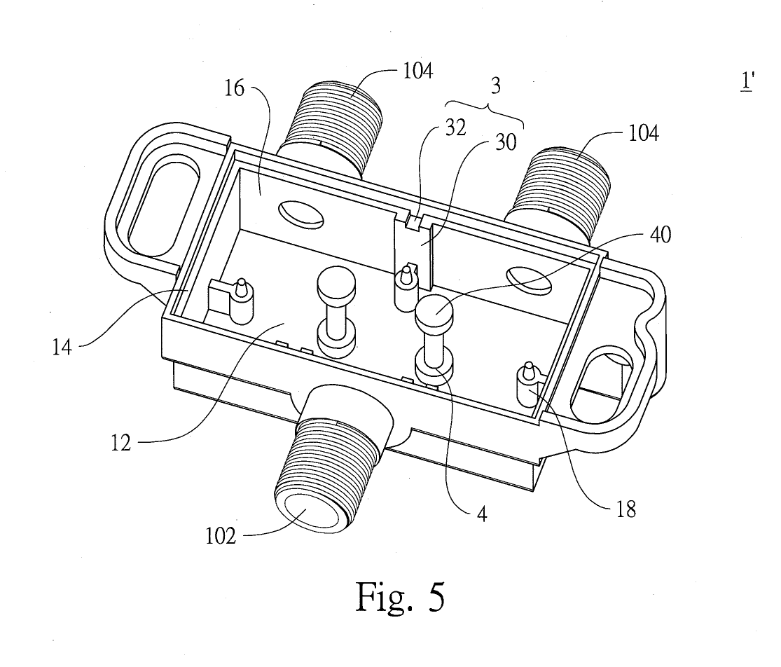

FIGS. 5˜6 illustrate a second embodiment of the impact resistant housing according to the present invention. In this embodiment, the impact resistant housing also comprises a base 1′ and a cover 2″, where the base 1′ is also provided on its outer peripheries with one signal input terminal 102 and two signal output terminals 104.

As shown in FIG. 5, in addition to the bottom 12, the top opening, the peripheral recession portion 14, the internal walls 16, and connection parts 18, the base 1′ also has three support seats 3 and two anti-impact bars 4. Each support seat 3 is used to support part of one strengthening rib 26 and is protruded from one internal wall 16 of the base 1′. Each anti-impact bar 4 is located on the bottom 12 of the base 1′ and is made by rigid material. Moreover, additional impact bars can be included to increase the strength.

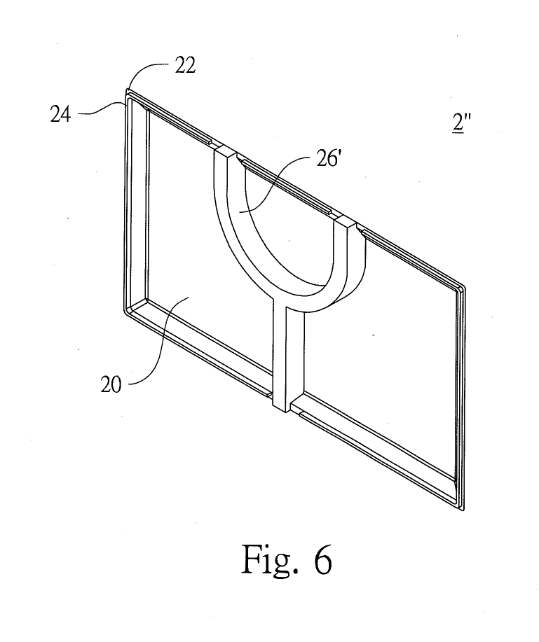

In the second embodiment, as shown in FIG. 6, plural strengthening ribs 26′ that are provided on the internal surface 20 of the cover 2″ are arranged to be in Y shape and have three end parts. Besides, as shown in FIG. 5, each support seat 3 includes a vertical part 30 and a recessed part 32 provided on top of the vertical part 30. In this embodiment, the vertical part 30 of the support seat 3 is extended to the bottom 12 of the base 1′.

By this arrangement, the end parts of the strengthening ribs 26′ can be held by the recessed parts 32 of the support seats 3. Thereby, when the cover is connected (such as soldered) to the base, it can provide better resistance against the impact from external force.

The anti-impact bar 4 is preferably uprightly disposed on the bottom 12 of the base 1′. Besides, the anti-impact bar 4 is preferably made by metal. However, other kinds of material with similar strength also could be used. In this embodiment, the anti-impact bar 4 is configured to form a T-shape bar and has a surface 40 arranged to face the internal surface of the cover. Thereby, when the cover 2″ is subject to impact from external force, the surface 40 of the anti-impact bar 4 would support the cover, so as to protect the circuit board and electrical signal lines inside the base 1′.

In order to evaluate the anti-impact performance of the impact resistant housing according to the present invention, a Falling Ball Test can be used. In this test, a heavy ball is used and released at a height above from the signal splitter case. As the test results reveal, the two embodiments of the impact resistant housing have excellent capability of resisting the impact exerted by the falling heavy ball.

Accordingly, as disclosed in the above description and attached drawings, the present invention can provide an impact resistant housing with enhanced structural strength for use with devices designed to split, amplify, or modulate CATV and satellite signals. Thereby, it is able to protect the circuit board and electrical signal lines placed inside the impact resistant housing from the impact of external force.

Although the embodiments of the present invention have been described in detail, many modifications and variations may be made by those skilled in the art from the teachings disclosed hereinabove. Therefore, it should be understood that any modification and variation equivalent to the spirit of the present invention be regarded to fall into the scope defined by the appended claims.

What is claimed is:

1. An impact resistant housing for data signal devices, comprising:
a base, including a bottom, a top opening, and a peripheral recession portion that is recessed from internal walls of the base and located adjacent to the top opening; and
a cover, including an internal surface, where the internal surface has peripheries connected to the peripheral recession portion of the base and is provided peripherally with a protruded portion adjacent to the peripheries of the cover;
wherein, when the cover is connected to the base, the protruded portion of the cover borders with the internal walls of the base.

2. The impact resistant housing as claimed in claim 1, wherein the cover further includes at least one strengthening rib disposed on the internal surface of the cover.

3. The impact resistant housing as claimed in claim 2, wherein the cover includes plural strengthening ribs and the plural strengthening ribs are arranged to cross with each other.

4. The impact resistant housing as claimed in claim 3, wherein the base further includes at least one support seat for supporting the strengthening ribs and each support seat is protruded from one internal wall of the base.

5. The impact resistant housing as claimed in claim 4, wherein each support seat includes a vertical part and a recessed part provided on top of the vertical part.

6. The impact resistant housing as claimed in claim 2, wherein the cover includes plural strengthening ribs and the plural strengthening ribs are arranged to be in Y shape.

7. The impact resistant housing as claimed in claim 6, wherein the base further includes at least one support seat for at least partially supporting the strengthening ribs and each support seat is protruded from one internal wall of the base.

8. The impact resistant housing as claimed in claim 7, wherein each support seat includes a vertical part and a recessed part provided on top of the vertical part.

9. The impact resistant housing as claimed in claim 1, wherein the base further includes at least one anti-impact bar, each of which is made by rigid material and is provided inside the base.

10. The impact resistant housing as claimed in claim 9, wherein each anti-impact bar is provided on the bottom of the base.

11. The impact resistant housing as claimed in claim 9, wherein each anti-impact bar has a surface facing the internal surface of the cover.

12. The impact resistant housing as claimed in claim 9, wherein each anti-impact bar is made by metal.

13. The impact resistant housing as claimed in claim 9, wherein each anti-impact bar is configured to be a T-shape bar.

14. The impact resistant housing as claimed in claim 1, wherein the peripheries of the internal surface of the cover are soldered to the peripheral recession portion of the base.
